(19) United States
(12) Patent Application Publication
(10) Pub. No.: US 2011/0157831 A1
(43) Pub. Date: Jun. 30, 2011

(54) LOCKING STRUCTURE AND METHOD FOR MANUFACTURING THE SAME AND HEAT DISSIPATION DEVICE USING THE SAME

(75) Inventors: WEI-CHENG NIE, Shenzhen City (CN); HONG-CHENG YANG, Shenzhen City (CN)

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/781,822

(22) Filed: May 18, 2010

(30) Foreign Application Priority Data
Dec. 28, 2009 (CN) 200910312435.9

(51) Int. Cl. H05K 7/20; F16B 39/28; B23P 11/00

(52) U.S. Cl. 361/704; 361/700; 411/103; 29/525.11

(57) ABSTRACT

A locking structure for assembling a first component to a second component. The locking structure includes a nut embedded into the first component and a bolt. The nut defines a groove in a circumferential periphery thereof. The first component forms a protrusion engaging into the grove of the nut. The bolt extends through the second component and screws into the nut.

### BACKGROUND

1. Technical Field

The present disclosure relates to locking structures and, more particularly, relates to a locking structure with a threaded nut, a method for manufacturing the locking structure and a heat dissipation device using the locking structure.

2. Description of Related Art

Generally, various components of numerous kinds of products are assembled together using locking structures such as bolts. For example, a typical heat dissipation device for dissipating heat generated by an electronic device (e.g. a central processing unit) includes components such as a heat sink, a clip, and a heat pipe. Bolts are of used to assemble these various components together.

With the development of electronics technology, electronic devices used in electronic apparatuses are being made to have more and more powerful operating capacity. An example is a central processing unit (CPU) used in a notebook computer. Nowadays, a CPU can have huge processing capacity. Yet modern electronic apparatuses are being made smaller and thinner. The heat dissipation device, including the components and the bolts securing the components, needs to also be made thin to suit the configuration of the electronic apparatus. However, the components of the heat dissipation device secured by the bolts may be so thin as to make the use of the bolts problematic. In particular, when a bolt is screwed into a component, the bolt is prone to be stripped or loosen from the component due to the limited surface areas available for threaded and frictional engagement. That is, conventional locking structures do not necessarily meet the needs of contemporary electronic apparatuses.

What are needed, therefore, are a locking structure which can overcome the limitations described above, a method for manufacturing such locking structure, and a heat dissipation device using the locking structure.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an assembled, isometric view of a heat dissipation device of an embodiment of the present disclosure.

FIG. 2 is an exploded view of the heat dissipation device of FIG. 1.

FIG. 3 shows an enlarged view of a nut of a locking structure of the heat dissipation device of FIG. 2.

FIG. 4 is a cross-sectional view of the heat dissipation device of FIG. 1, taken along line IV-IV thereof.

FIG. 5A is an inverted, side cross-sectional view of the nut of FIG. 3 ready to be secured to a base of the heat dissipation device of FIG. 2.

FIG. 5B is similar to FIG. 5A, but showing the nut pre-secured to the base.

FIG. 5C is similar to FIG. 5B, but showing the nut fully secured to the base.

### DETAILED DESCRIPTION

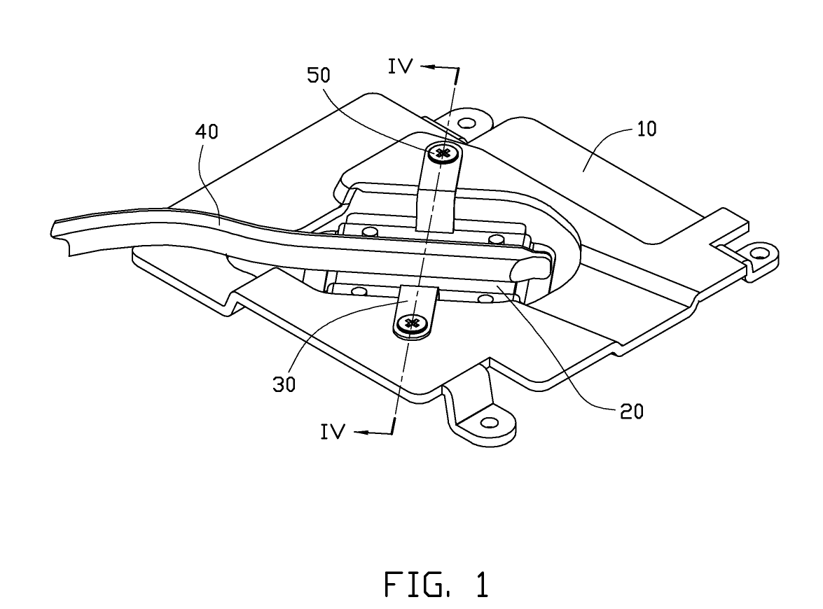

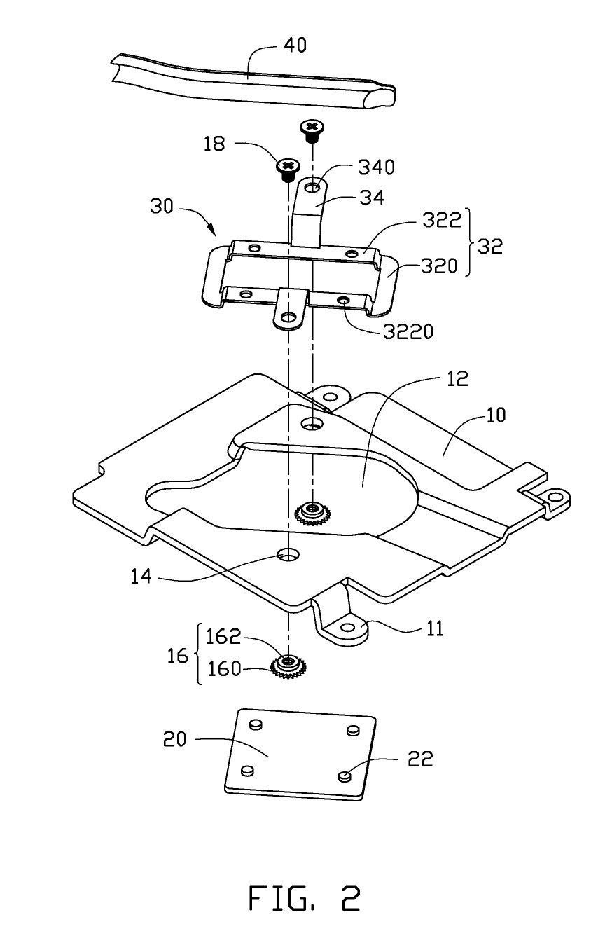

Referring to FIGS. 1-2, a heat dissipation device of an embodiment of the present disclosure is illustrated. The heat dissipation device comprises a base 10, a heat absorbing plate 20, a securing member 30 connecting with the base 10 and the heat absorbing plate 20, and a locking member 50 locking the securing member 30 to the base 10. A heat pipe 40 is in thermal contact with the heat absorbing plate 20. The locking member 50 comprises a nut 16 engaging with the base 10, and a bolt 18 extending through the securing member 30 and engaging with the nut 16.

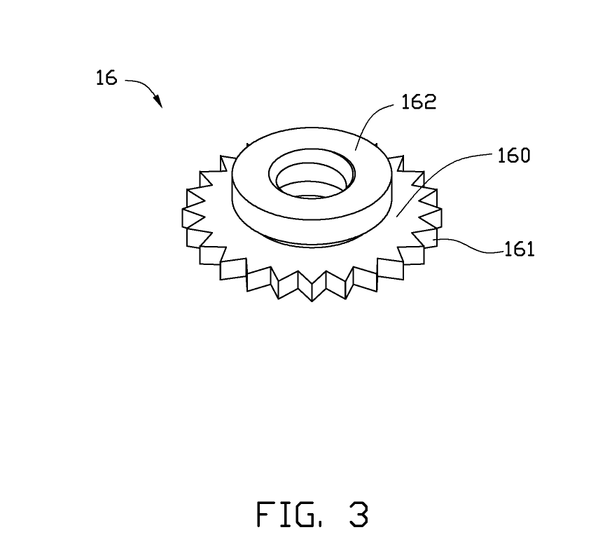

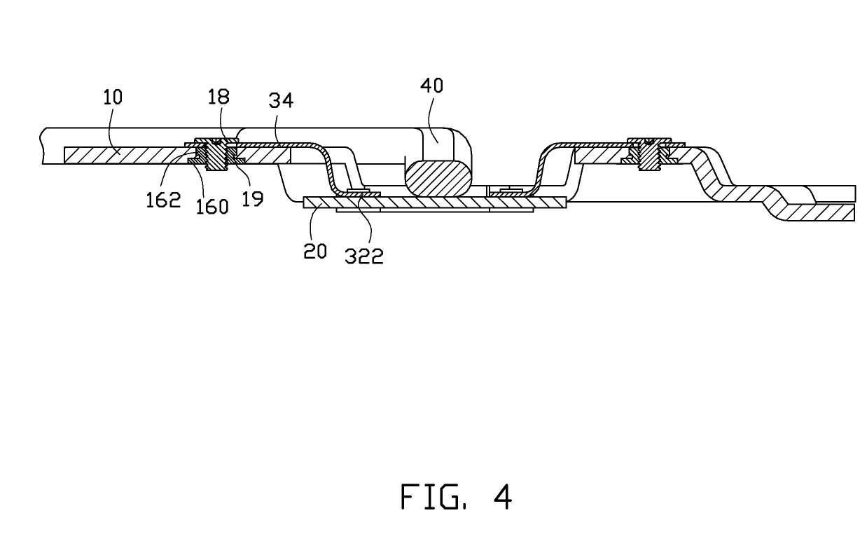

Referring to also FIGS. 3-5C also, the base 10 is substantially rectangular, and is integrally made from a piece of metal such as aluminum. The base 10 comprises a main body (not labeled), and a plurality of spaced locking arms 11 extending from a periphery of the main body. Each of the arms 11 defines a through hole. A plurality of fasteners (not shown) are extended through the arms 11 and into a printed circuit board to fasten the base 10 and the printed circuit board together. An opening 12 is defined in a central portion of the main body for exposing the heat absorbing plate 20. The opening 12 is elongated in this embodiment. The base 10 defines two engaging holes 14 at two opposite sides of the opening 12, respectively, for receiving two corresponding nuts 16 therein.

Each nut 16 comprises a chassis 160 and a sleeve 162 extending from the chassis 160. In this embodiment, the chassis 160 is circular in shape. The chassis 160 forms a plurality of first teeth 161 along a circumferential periphery thereof. The base 10 forms a plurality of second teeth (not shown) in the corresponding engaging hole 14. The second teeth are complementary with the first teeth 161 of the chassis 160, such that the first teeth 161 of the chassis 160 can joggle with the second teeth of the base 10. Thus, the nut 16 can be locked and prevented from rotating in the engaging hole 14. The sleeve 162 is hollow and has a shape of a cylinder (or column) The chassis 160 and the sleeve 162 are coaxial. The sleeve 162 has an external diameter less than that of the chassis 160. In this embodiment, the external diameter of the sleeve 162 is substantially equal to the diameter of the engaging hole 14, such that the sleeve 162 can be snugly received in the engaging hole 14. The combined chassis 160 and sleeve 162 form a screw thread in an interior surface thereof. The sleeve 162 defines an annular groove 1620 in an external periphery thereof adjacent to the chassis 160. The base 10 forms an annular protrusion 19 extending inwardly from an inner wall of the engaging hole 14 and engaging in the groove 1620 of the sleeve 160 after the nut 16 is secured to the base 10, such that the nut 16 can be locked and prevented from moving along an axial direction of the engaging hole 14. The nut 16 is made from material which is more rigid than that of the base 10, such as cast iron, steel, copper, or any suitable alloy including any of the foregoing.

The heat absorbing plate 20 is substantially rectangular, and is integrally made from a piece of material with good heat conductivity, such as copper or aluminum. The heat absorbing plate 20 comprises a main body, and a plurality of spaced posts 22 extending upwardly from the main body. The main body of the heat absorbing plate 20 has a first face and a second face opposite to the first face. The first face is for contacting an electronic device mounted on the printed circuit board and absorbing heat from the electronic device. The posts 22 extend perpendicularly from the second face of the main body of the heat absorbing plate 20.

The securing member 30 is flexible. In this embodiment, the securing member 30 is in the form of a bent metal sheet. The securing member 30 comprises a frame 32, and two elastic arms 34 respectively extending from two opposite sides of the frame 32. The frame 32 defines a window in a central portion thereof, and comprises two opposite clamping portions 320 and two opposite pressing portions 322 around the window. Each pressing portion 322 defines two spaced positioning apertures 3220 in two end parts thereof, respectively. The pressing portions 322 can span over and press two opposite lateral portions of the second face the main body of the heat absorbing plate 20. The two elastic arms 34 each comprise a first portion extending outwardly and upwardly from a central part of the corresponding pressing portion 322, and a second portion extending outwardly and horizontally from a distal end of the first portion. A distal end of the second portion of each elastic arm 34 defines a though hole 340 therein, for extension of a bolt 18 therethrough. The bolt 18 comprises a threaded portion capable of extending through the though hole 340 and screwing into the sleeve 162 of the nut 16 to fasten the securing member 30 to the base 10.

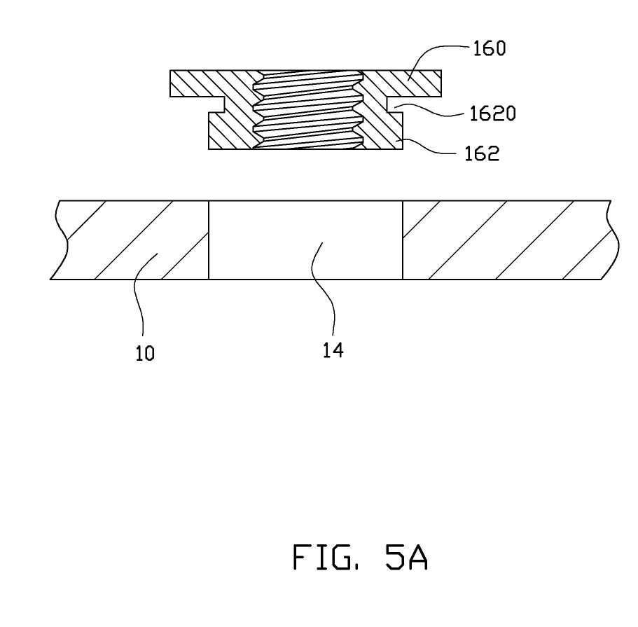

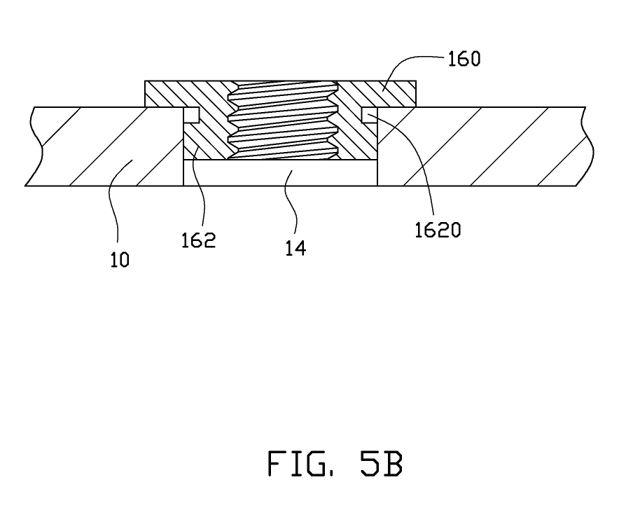

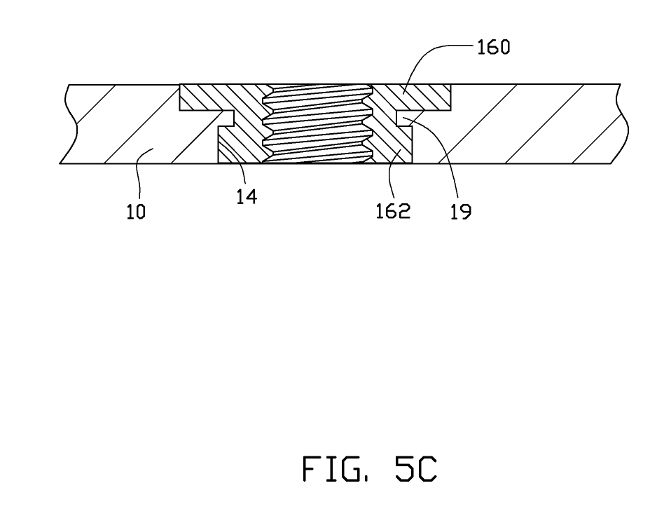

Referring to FIGS. 5A, 5B and 5C, in assembly, each nut 16 is inserted to the corresponding engaging hole 14 of the base 10. The nut 16 is disposed within the engaging hole 14 of the base 10 as shown in FIG. 5B from a place above the base 10 as viewed in FIG. 5A. After the sleeve 162 is totally received in the engaging hole 14 and the chassis 160 is blocked from entering the engaging hole 14 by a top face of the base 10, the chassis 160 is punched toward the base 10 until the chassis 160 is embedded into the base 10. As shown in FIG. 5C, when the nut 16 is fixed into position in this way, a part of a wall of the base 10 surrounding the engaging hole 14 is deformed to form the protrusion 19 engaged into the groove 1620 of the sleeve 162 due to pressure generated by the chassis 160. The base 10 around the chassis 160 simultaneously forms the plurality of second teeth joggled with the first teeth 161 of the chassis 160. Therefore, the nut 16 is firmly locked in the engaging hole 14 of the base 10 in circumferential directions of the engaging hole 14 and axial directions of the engaging hole 14. In this embodiment, the chassis 160 is coplanar with the base 10 at bottom faces thereof. Referring back to FIGS. 2 and 3, the posts 22 of the heat absorbing plate 20 are firmly positioned into corresponding positioning apertures 3220 of the pressing portions 322 of the securing member 30 by punching. Thereby, the heat absorbing plate 20 is firmly attached to the securing member 30. The heat absorbing plate 20 and the frame 32 of the securing member 30 are positioned to be at a level below the base 10, via the opening 12 of the base 10. The second portions of the elastic arms 34 are positioned on the base 10, with the through holes 340 in line with the corresponding engaging holes 14 of the base 10. The threaded portions of the bolts 18 are extended through the corresponding through holes 340 and screwed into the nuts 16 in the base 10. Thus, the base 10 and the heat absorbing plate 20 are firmly assembled together via the securing member 30.

The heat pipe 40 is flattened and has a portion thereof positioned on and contacting the second face of the heat absorbing plate 20, for transferring heat absorbed by the heat absorbing plate 20 to another location (not shown).

It is believed that the embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A locking structure for attaching a first component to a second component, the locking structure comprising:
a nut embedded into the first component, the nut defining a groove in a circumferential periphery thereof, the first component having a protrusion engaged in the groove of the nut; and
a bolt extending through the second component and threadedly engaged in the nut.

2. The locking structure of claim 1, wherein the nut comprises a chassis and a sleeve extending from the chassis, the groove being defined in a circumferential periphery of the sleeve.

3. The locking structure of claim 2, wherein the chassis has a diameter larger than that of the sleeve.

4. The locking structure of claim 2, wherein the chassis has a plurality of teeth at a periphery thereof, the teeth joggled with the first component.

5. A method for manufacturing a locking structure, the method comprising:
providing a first component with an engaging hole therein;
providing a second component;
providing a nut comprising a chassis and a sleeve extending from the chassis, the chassis having a external diameter larger than that of the sleeve, the sleeve defining a groove in a periphery thereof;
inserting the sleeve into the engaging hole of the first component until the chassis is blocked from entering the engaging hole by the first component;
punching the chassis toward the first component so that the chassis is embedded in the first component and a portion of the first component is extruded into the groove thereby forming a protrusion engaged in the groove of the sleeve; and
providing a bolt, and extending the bolt through the second component and engaging the bolt in the nut.

6. The method for manufacturing a locking structure of claim 5, wherein the chassis and the sleeve are coaxial with each other.

7. The method for manufacturing a locking structure of claim 5, wherein the chassis and the first component are coplanar at bottom faces thereof after the chassis is punched into the first component.

8. The method for manufacturing a locking structure of claim 5, wherein the chassis forms a plurality of first teeth at a periphery thereof, and the first component forms a plurality of second teeth joggling with the first teeth of the chassis when the chassis is punched into the first component.

9. A heat dissipation device comprising:
a plate for absorbing heat generated from an electronic device;
a base for securing the heat dissipation device to the electronic device;
a securing member connecting the plate and the base; and
a locking structure comprising a nut embedded in the plate and a bolt engaging with the securing member and the nut;
wherein the nut defines a groove in a circumferential periphery thereof, and the plate has a protrusion engaged in the groove of the nut.

10. The heat dissipation device of claim 9, wherein the securing member is elastic.

11. The heat dissipation device of claim 9, wherein securing member comprises a pressing portion engaging with the plate and an arm engaging with the bolt.

12. The heat dissipation device of claim 11, wherein the arm of the securing member extends from the pressing portion and is curved.

13. The heat dissipation device of claim 11, wherein the base defines an opening, the plate and the pressing portion are capable of being extended through the opening and are located at a first side of the opening, and the arm has a portion that is located at a second side of the opening which is opposite to the first side of the opening and that is positioned on the base.

14. The heat dissipation device of claim 11, wherein the plate comprises a main body and a post, the post extending into the pressing portion of the securing member.

15. The heat dissipation device of claim 9, wherein the nut comprises a chassis and a sleeve extending from the chassis, the groove being defined in a periphery of the sleeve.

16. The heat dissipation device of claim 15, wherein the nut has a diameter larger than that of the sleeve.

17. The heat dissipation device of claim 9, further comprising a heat pipe, wherein the heat pipe is located on the securing member and in contact with plate.
